(19) United States
(12) Patent Application Publication
(10) Pub. No.: US 2015/0156885 A1
(43) Pub. Date: Jun. 4, 2015

(54) METHOD FOR MANUFACTURING AN ELECTRIC DEVICE BY CONNECTING A WIRING BOARD TO AN OBJECT AND ELECTRIC DEVICE INCLUDING A BOARD

(71) Applicant: Sumitomo Electric Device Innovations, Inc., Yokohama-shi (JP)

(72) Inventor: Haruyoshi ONO, Yokohama-shi (JP)

(21) Appl. No.: 14/555,293

(22) Filed: Nov. 26, 2014

(30) Foreign Application Priority Data
Nov. 29, 2013 (JP) 2013-248597

(51) Int. Cl. H05K 1/18; H05K 1/11; H05K 3/34

(52) U.S. Cl. CPC H05K 1/189; H05K 3/3447; H05K 1/181; H05K 1/115; H05K 1/118

(57) ABSTRACT

A method for manufacturing an electric device by connecting a wiring board to an object is disclosed. This method for manufacturing an electric device comprises: applying a wiring board having a first via hole on a mounting face of an object to fix the wiring board; placing a heater having a recess to the wiring board, the heater being adjusted so that the recess overlaps a boundary between the first via hole and a surface of the wiring board; and melting a soldering metal so that the soldering metal enters into the recess and the first via hole.

### TECHNICAL FIELD

The present invention relates to a method for manufacturing an electric device by connecting a wiring board to an object, and an electric device including the wiring board.

### BACKGROUND

A semiconductor device such as an optical semiconductor device is packaged. A board such as a flexible printed board (hereinafter, described as a flexible board) is connected to a lead of a semiconductor package, and power supply, input and output of signals, or the like is performed through the board. The board is connected to the lead using a soldering metal. Connection using the soldering metal is performed through soldering (Japanese Patent Application Laid-Open Publication No. Hei7-273435).

### SUMMARY

However, it is difficult to realize stable connection using soldering depending on the amount of the soldering metal, wettability of the soldering metal, a temperature profile, or the like.

One aspect of the present application relates to a method for manufacturing an electric device. The method for manufacturing the electric device comprises: applying a wiring board having a first via hole on a mounting face of an object to fix the wiring board; placing a heater having a recess to the wiring board, the heater being adjusted so that the recess overlaps a boundary between the first via hole and a surface of the wiring board; and melting a soldering metal so that the soldering metal enters into the recess and the first via hole.

Another aspect of the present application relates to an electric device. The electric device comprising: a wiring board having a first via hole on a mounting face of an object to fix the wiring board; and a soldering metal extending inside the first via hole and on a surface of the wiring board, wherein the soldering metal has a first projection and a recess of the wiring board located on an outside of the first via hole, and a thickness of the first projection is larger than that of the recess.

### BRIEF DESCRIPTION OF THE DRAWINGS

The foregoing and other purposes, aspects and advantages will be better understood from the following detailed description of a preferred embodiment of the invention with reference to the drawings, in which:

FIG. 1 is a cross-section view illustrating a method for manufacturing an optical module according to a first embodiment;

FIG. 2 is a plan view illustrating a semiconductor package;

FIG. 3A is a plan view illustrating an upper face of a flexible board, FIG. 3B is a plan view illustrating a lower face of a heater, FIG. 3C is a cross-section view along a line IIIc-IIIc in FIG. 3B;

FIG. 4A is a plan view illustrating soldering, FIG. 4B is a plan view illustrating a flexible board after soldering;

FIG. 5A is a cross-section view along a line Va-Va in FIG. 4B, FIG. 5B is a cross-section view along a line Vb-Vb in FIG. 4B;

FIG. 6A is a plan view illustrating a heater in a comparative example, FIG. 6B is a cross-section view along a line VIb-VIb in FIG. 6A;

FIG. 7A is a plan view illustrating a flexible board after soldering, FIG. 7B is a cross-section view along a line VIIb-VIIb in FIG. 7A, FIG. 7C is a cross-section view along a line VIIc-VIIc in FIG. 7A,

FIG. 8A is a plan view illustrating a lower face of the heater, FIG. 8B is a cross-section view along a line VIIIb-VIIIb in FIG. 8A; and

FIG. 9A is a plan view illustrating a flexible board after soldering, FIG. 9B is a cross-section view along a line IXb-IXb in FIG. 9A, and FIG. 9C is a cross-section view along a line IXc-IXc in FIG. 9A.

### DETAILED DESCRIPTION

Embodiments of the present invention will be described.

One aspect of the present embodiment relates to a method for manufacturing an electric device. The method for manufacturing the electric device comprises disposing a wiring board on a mounting face, the wiring board having a first terminal provided on a first face, a second terminal provided on a second face which is an opposite side of the first face, and a first via hole connecting the first terminal to the second terminal; adjusting a position of a heater having a first recess so that the first recess overlaps with the first via hole and a portion of the wiring board outside of the first via hole; making the heater abut on the wiring board after the adjusting; melting a soldering metal in a state the heater abuts on the wiring board so that the melted soldering metal intrudes into the first via hole and the first recess of the heater; and solidifying the melted soldering metal so as to connect the wiring board to the mounting face.

According to this embodiment, the soldering metal is melted by way of soldering, and the melted soldering metal flows on the first face through the first via hole. The soldering metal flowing into the first recess of the heater forms the projection. Because the soldering metal has the projection, the soldering metal is thick on the first via hole. Therefore, the wiring board is rigidly bonded to another board. Because a surface area of the soldering metal becomes larger than one in which there is no projection, heat is efficiently transferred from the heater to the soldering metal. As a result, heat circulation efficiency between the soldering metal on the first face side and the soldering metal on the second face side is improved, and the soldering metal is effectively melted. By this means, wettability between the soldering metal and the electronic component is improved. As described above, according to the above-described embodiment, it is possible to provide a method for manufacturing an electric device by connecting a wiring board to another board which realizes connection with high reliability.

In the above-described embodiment, it is also possible that the wiring board has a second via hole connecting the first terminal to the second terminal, and the heater is adjusted so that the first recess is provided over both of the first and the second via holes in the adjusting. According to this embodiment, a projection is provided over the first and the second via holes. Compared to a case where one projection is formed on one via hole, strength of bonding is improved. Accordingly, reliability of connection increases.

Another aspect of the present embodiment relates to an electric device. The electric device comprising a wiring board having a first terminal provided on a first face, a second terminal provided on a second face which is an opposite side of the first face, and a first via hole connecting the first terminal to the second terminal; another board having a mounting face; a soldering metal extending between the second terminal of the wiring board and the mounting face of the another board, inside the first via hole and on a surface of the first terminal, wherein the soldering metal has a first projection provided on the first via hole and on a portion of the wiring board located on an outside of the first via hole, the first projection projecting from the first face.

According to this embodiment, because the soldering metal has a projection, the soldering metal is thick on the first via hole. Therefore, the wiring board is rigidly bonded to another board. Because a surface area of the soldering metal becomes larger than one in which there is no projection, heat is efficiently transferred to the soldering metal. As a result, heat circulation efficiency between the soldering metal on the first face side and the soldering metal on the second face side is improved, and the soldering metal is effectively melted. By this means, wettability between the soldering metal and the electronic component is improved. As described above, according to the above-described embodiment, it is possible to provide an electric device including a wiring board which realizes connection with high reliability.

A more detailed example of an embodiment according to the present invention will be described below with reference to the accompanying drawings. In the description of the drawings, the same element will be designated by the same reference numeral and a duplicate description thereof will be omitted. Further, in each drawing used for the following description, a scale is properly changed in order to illustrate each member with an identifiable size.

### First Embodiment

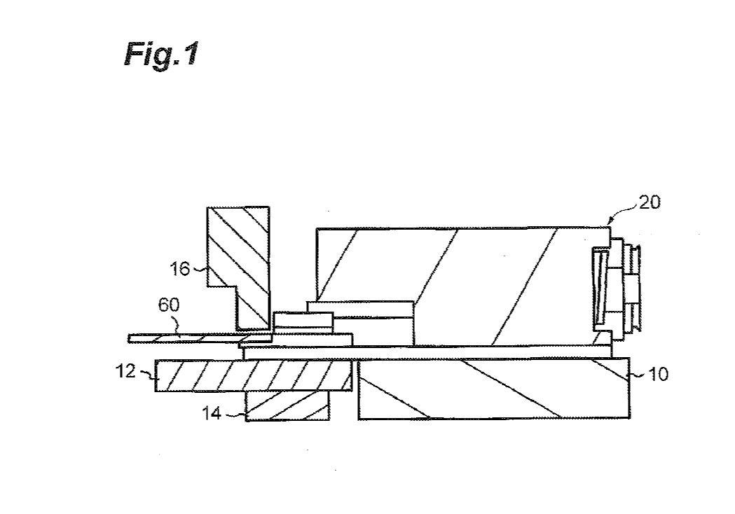

FIG. 1 is a cross-section view illustrating a method for manufacturing an optical module (optical device) according to a first embodiment. As illustrated in FIG. 1, a semiconductor package 20 (electronic component) is mounted on jigs 10 and 12. A ceramic heater 14 is disposed below the jig 12. A flexible hoard 60 (wiring board) is disposed on a lead not illustrated in FIG. 1) of the semiconductor package 20. A heater 16 presses the flexible board 60 against the lead of the semiconductor package 20 from above to perform soldering. By way of soldering, the flexible board 60 is electrically connected to the lead using a soldering metal. The jig 10 is formed with a metal such as, for example, aluminum (Al). The jig 12 is formed with a metal such as, for example, copper (Cu). The jigs 10 and 12 may be formed with an insulating material.

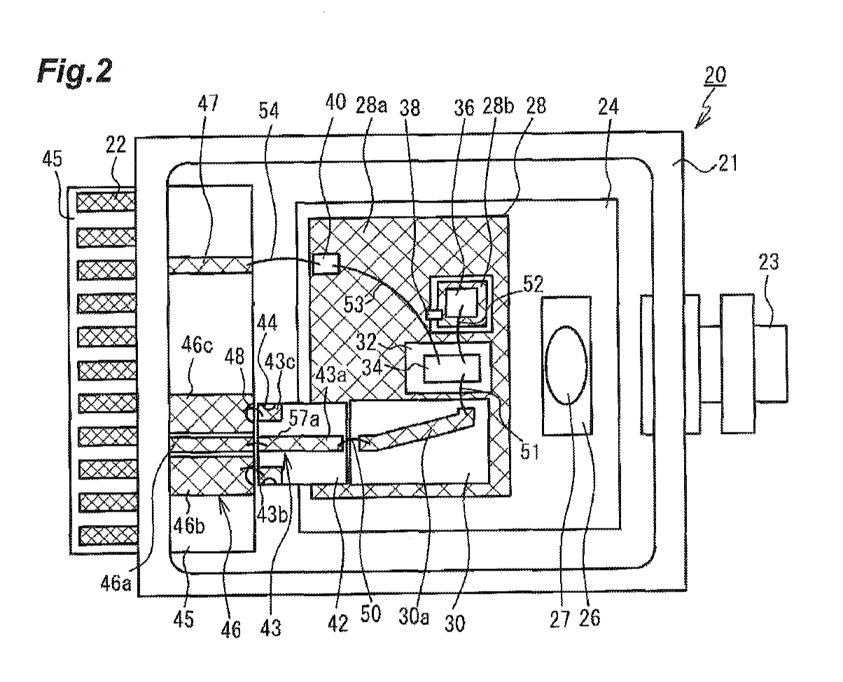

FIG. 2 is a plan view illustrating the semiconductor package 20. As illustrated in FIG. 2, a temperature control unit such as a TEC (Thermoelectric Cooler) 24 is disposed on a bottom face of a housing 21. of the semiconductor package 20. On the TEC 24, a carrier 28 and a lens holder 26 are disposed. The carrier 28 is made of a material with an insulating properties and high thermal conductivity. The carrier 28 is, for example, aluminum oxide or ceramics. A lens 27 is held in the lens holder 26. On an upper face of the carrier 28, ground patterns 28a and 28b are provided. On the ground pattern 28a, boards 42 and 30, a subcarrier 32 and a capacitor 40 are provided. A resistor 38 is connected between the ground patterns 28a and 28b. A capacitor 36 is provided on the ground pattern 28b.

The subcarrier 32 is, for example, a dielectric board. A semiconductor laser 34 (LD (Laser Diode) element) is disposed on the subcarrier 32. A signal line 30a is fowled on an upper face of the board 30. The signal line 30a and the ground pattern 28a on the upper face of the carrier 28 form a micro strip line.

A receptacle 23 is fixed on a front face of the housing 21. A board 45 is embedded in a rear side wall of the housing 21. The board 45 serves as a feed-through. On the board 45, a coplanar line 46 and a signal line 47 are provided. The coplanar line 46 is formed with a signal line 46a and ground patterns 46b and 46c. The signal lines 46a and 47 and the ground patterns 46b and 46c of the board 45 are electrically connected to the signal lines 22, respectively. On the lower face of the board 45, a ground pattern (not illustrated) is provided. The ground patterns 46b and 46c are connected to the ground pattern on the lower face through via holes 48, respectively.

The board 42 serves as a bridge between the board 45 and the board 30. On an upper face of the board 42, a signal line 43a and ground patterns 43b and 43c are provided. On a lower face of the board 42, a ground layer which is not illustrated is provided. The signal line 43a and the ground patterns 43b and 43c form a coplanar line 43. The signal line 43a and the ground pattern on the lower face form a micro strip line. The ground patterns 43b and 43c are connected to the ground pattern on the lower face through via holes 44, respectively.

The signal line 43a of the board 42 is electrically connected to the signal line 30a of the hoard 30 through a bonding wire 50. The signal line 30a is electrically connected to the semiconductor laser 34 through a bonding wire 51. The semiconductor laser 34 is electrically connected to the capacitor 36 through a bonding wire 52. The semiconductor laser 34 is electrically connected to the capacitor 40 through a bonding wire 53. The capacitor 40 is electrically connected to the signal line 47 through a bonding wire 54.

A power-supply voltage is supplied to the semiconductor laser 34 through the signal line 22, the signal line 47 and the capacitor 40. A laser drive IC (Integrated Circuit, not illustrated) is disposed outside the semiconductor package 20. The laser drive IC is connected to the signal line 22 through the flexible board 60 illustrated in FIG. 1. The laser drive IC amplifies an input signal which is a high frequency signal and outputs the amplified signal. The output input signal is input to the semiconductor laser 34 through the coplanar line 46 of the board 45, the coplanar line 43 and the micro strip line of the board 42, and the micro strip line of the board 30. The output light of the semiconductor laser 34 is focused by the lens 27 and output to an optical fiber (not illustrated) which is inserted into the receptacle 23.

The TEC 24 maintains a constant temperature of the semiconductor laser 34. By this means, it is possible to lock a wavelength of the output light. Because part of the board 45 is exposed to the outside of the housing 21, the temperature of the board 45 is substantially equal to the outside temperature. The board 42 is cooled down by the TEC 24. Because the ground pattern of the board 42 is separated from the ground pattern of the board 45, heat is less likely to be transferred between the boards 42 and 45, so that increase of the temperature of the semiconductor laser 34 is inhibited.

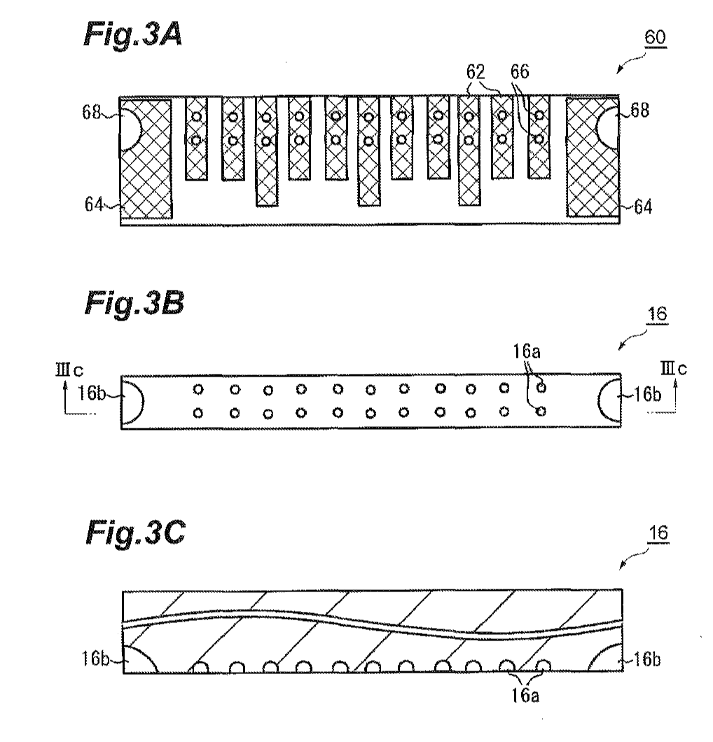

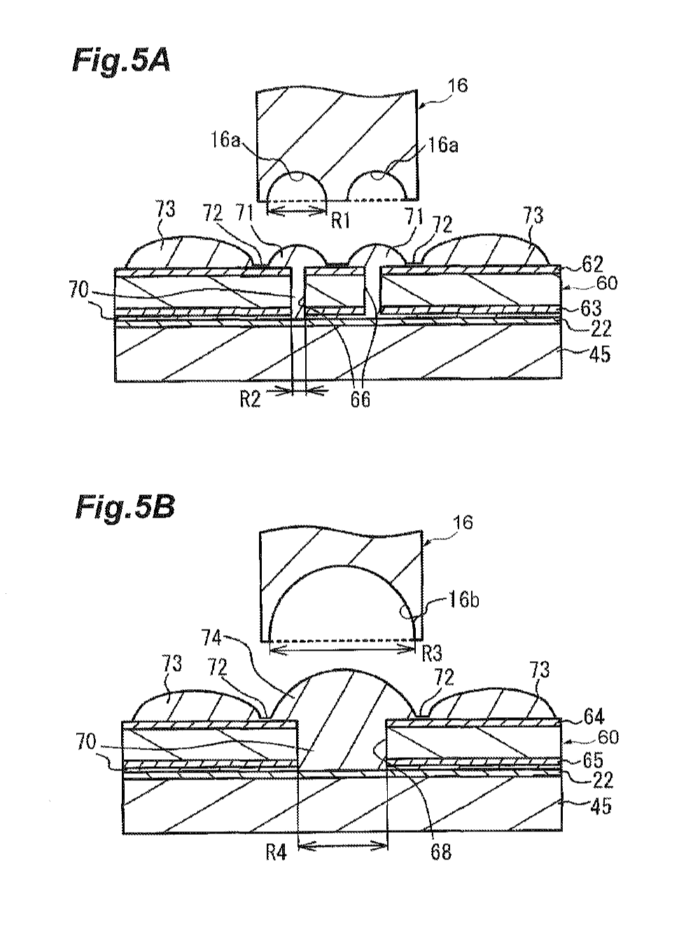

FIG. 3A is a plan view illustrating an upper face of the flexible board 60. As illustrated in FIG. 3A, a plurality of terminals 62 and two terminals 64 are provided on the upper face of the flexible board 60. Two via holes 66 are provided for one terminal 62. One via hole 68 is provided at each of the terminals 64. As will be described later with reference to FIG. 5A and FIG. 5B, terminals 63 and terminals 65 are provided on a lower face of the flexible board 60. The via holes 66 penetrate through the flexible board 60 and connect the terminals 62 on the upper face to the terminals 63 on the lower face, respectively. The via holes 68 penetrate through the flexible board 60 and connect the terminals 64 on the upper face to the terminals 65 on the lower face, respectively. The terminals 62 and 63 are terminals for inputting a power-supply voltage and inputting and outputting a high frequency signal. The terminals 64 and 65 have a reference potential. The soldering metal is preformed on the terminals 63 and 65 (which is not illustrated). It should be noted that the soldering metal does not have to be preformed on the terminals and may be applied upon bonding.

FIG. 3B is a plan view illustrating a lower face of the heater 16. FIG. 3C is a cross-section view along a line IIIc-IIIc in FIG. 3B. As illustrated in FIG. 3B and FIG. 3C, a plurality of recesses 16a and two recesses 16b are provided at a tip of the heater 16. The recesses 16a and 16b have curved upper faces. The position of the heater 16 is adjusted on the flexible board 60 so that the recesses 16a illustrated in FIG. 3B and FIG. 3C overlap with the via holes 66 and the flexible board 60 on the outside of the via hole 66 illustrated in FIG. 3A, respectively, and the recesses 16b overlap with the via holes 68 and the flexible board 60 on the outside of the via holes 68, respectively. As illustrated in FIG. 1, the flexible board 60 is soldered to the semiconductor package 20 using the heater 16.

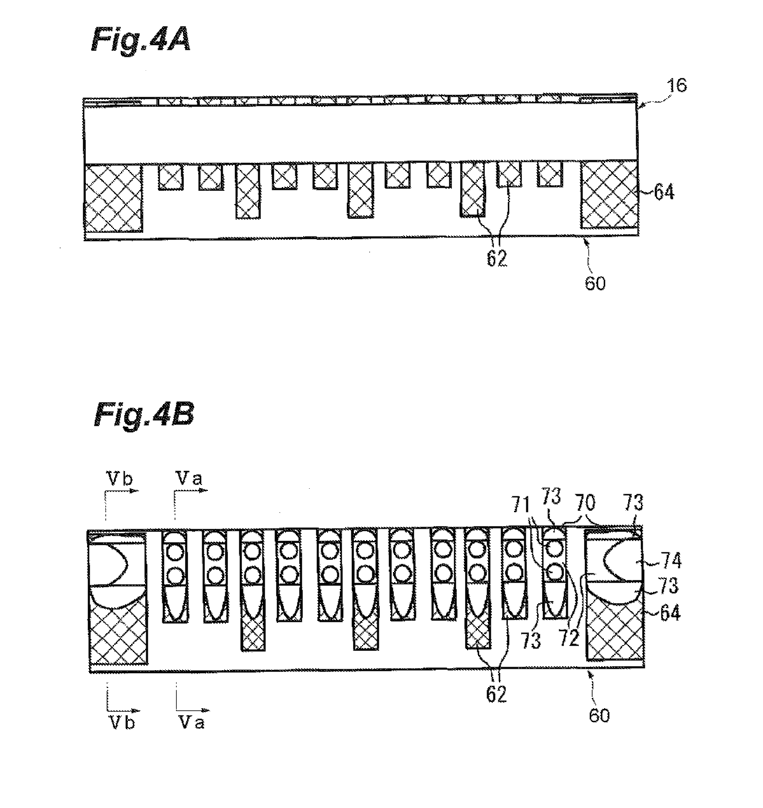

FIG. 4A is a plan view illustrating soldering. FIG. 4B is a plan view illustrating the flexible board 60 after soldering. FIG. 5A is a cross-section view along a line Va-Va in FIG. 4B. FIG. 5B is a cross-section view along a line Vb-Vb in FIG. 4B.

As illustrated in FIG. 4A, the heater 16 is brought into contact with the upper face of the flexible board 60. The heater 16 applies heat and pressure to the flexible board 60. As illustrated in FIG. 4B, a soldering metal 70 having the projection 71 and 73 and the recess 72 wets and spreads over the terminal 62. A soldering metal 70 having the projections 74 and 73 and the recess 72 wets and spreads over the terminal 64. It should be noted that the terminals are separated from each other and electrically insulated from each other. Detailed description will be provided with reference to the cross-section view.

A method for connecting the flexible board 60 to the mounting face of the board 45 will be described with reference to FIG. 1. At first, the flexible board 60 is mounted on the mounting face of the board 45. The heater 16 applies heat and pressure to the flexible board 60. The soldering metal 70 provided on the lower face of the flexible board 60 is melted by the heat transferred from the heater 16. The melted soldering metal 70 flows on the upper face through the via holes 66 as illustrated in FIG. 5A. The melted soldering metal 70 wets and spreads over the terminal 62 provided on the upper face of the flexible board 60 and the terminal 63 provided on the lower face. The terminal 63 is electrically connected to the signal line 22 through the soldering metal 70. Further, the terminals 63 is electrically connected to the terminal 62 through the soldering metal 70 inside the via holes 66. The melted soldering metal 70 is solidified after intruding into the recesses 16a of the heater 16 and forms the projections 71. The soldering metal 70 at a portion pressed against an end face (lower face in FIG. 5A) of the heater 16 forms recesses 72. At the outside of the recesses 72, projections 73 are formed.

As illustrated in FIG. 5B, the melted soldering metal 70 wets and spreads over the terminal 64 provided on the upper face of the flexible board 60 and the terminal 65 provided on the lower face. The terminal 65 is electrically connected to the signal line 22 through the soldering metal 70. Further, the terminal 65 is electrically connected to the terminal 64 through the soldering metal 70 inside the via hole 68. The soldering metal 70 which has intruded into the recess 16b of the heater 16 is solidified and forms a projection 74. At the outside of the projection 74, recesses 72 are formed. At the outside of the recesses 72, projections 73 are formed. The projections 71, 73 and 74 project further from the upper face of the flexible board 60.

Because the soldering metal 70 has projections 71 and 74, the soldering metal 70 is thick on the via holes 66 and 68. Therefore, the flexible board 60 is rigidly bonded to the signal line 22. Because a surface area of the soldering metal 70 becomes larger than one in which there is no projection, heat is efficiently transferred from the heater 16 to the soldering metal 70. As a result, heat circulation efficiency between the soldering metal on the upper face side and the soldering metal on the lower face side is improved, and the soldering metal 70 is effectively melted. By this means, wettability between the soldering metal 70 and the terminals is improved and wettability between the soldering metal 70 and the metal patterns is also improved. As described above, according to the first embodiment, it is possible to improve reliability of connection.

As illustrated in FIG. 5A, a radius R1 of the recess 16a is greater than a radius R2 of the via hole 66. By this means, the projection 71 which is larger than the via hole 66 is formed. As illustrated in FIG. 5B, a radius R3 of the recess 16b is greater than a radius R4 of the via hole 68. The projection 74 which is larger than the via hole 68 is foamed. Because the projections 71 and 74 are supported on the upper face of the flexible board 60, the soldering metal 70 is inhibited from flowing out to the lower face side. By this means, shapes of the projections 71 and 74 become stable. Because the shapes of the projections 71 and 74 become stable, it is possible to realize rigid bonding, which improves reliability of connection. As described above, it is preferable that the recess 16a of the heater 16 is larger than the via hole 66 and the recess 16b is larger than the via hole 68.

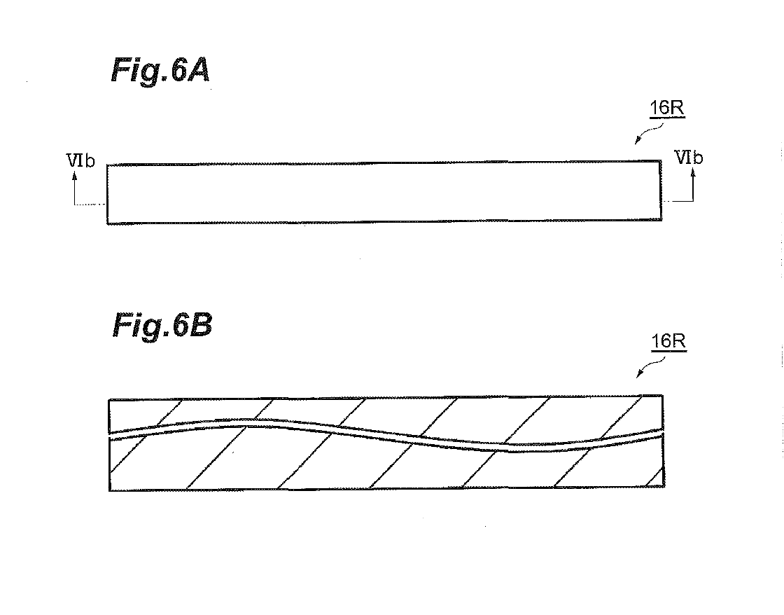

A comparative example will be described. The flexible board 60 is the same as that illustrated in FIG. 3A. The semiconductor package is the same as that illustrated in FIG. 2. FIG. 6A is a plan view illustrating a heater 16R in the comparative example. FIG. 6B is a cross-section view along a line VIb-VIb in FIG. 6A. As illustrated in FIG. 6A and FIG. 6B, a recess is not provided on the heater 16R.

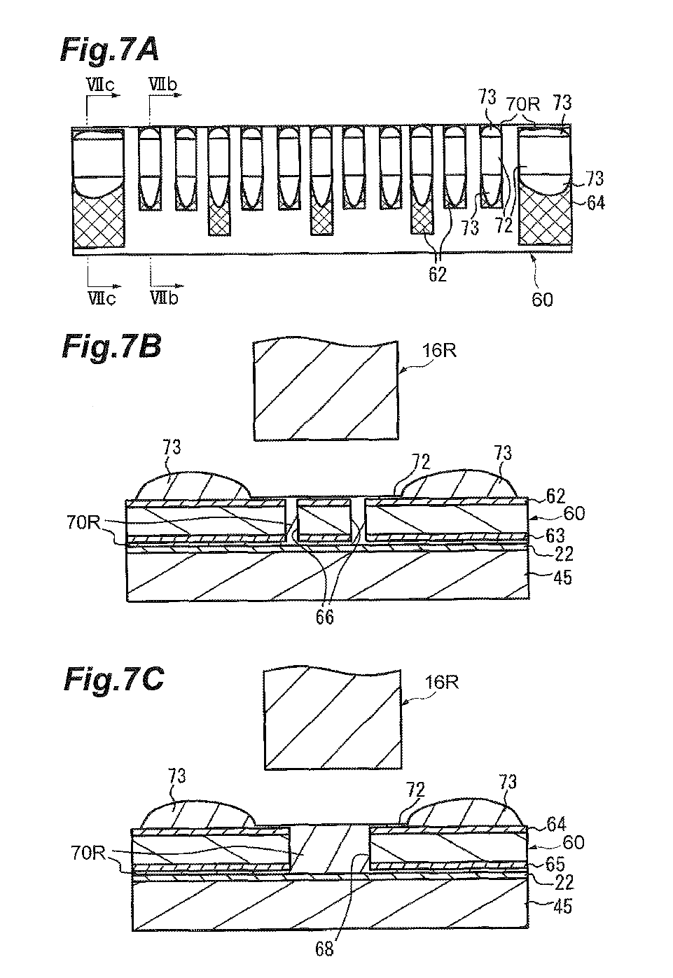

Soldering as illustrated in FIG. 4A is also performed in the comparative example. FIG. 7A is a plan view illustrating the flexible board 60 after soldering. FIG. 7B is a cross-section view along a line VIIb-VIIb in FIG. 7A. As illustrated in FIG. 7B, a projection 71 is not formed on a soldering metal 70R. The soldering metal 70R on the via hole 66 is pressed by a lower face of the heater 16R. Therefore, a recess 72 is formed on the via hole 66. FIG. 7C is a cross-section view along a line VIIc-VIIc in FIG. 7A. As illustrated in FIG. 7C, a projection 74 is not formed on the soldering metal 70R The soldering metal 70R on the via hole 68 is pressed by the lower face of the heater 16R. Therefore, a recess 72 is formed on the via hole 68.

As described above, in the comparative example, the thickness of the soldering metal 70R on the via holes 66 and 68 is thin. Therefore, strength of bonding is weak. Because a surface area of the soldering metal 70R is smaller than that in the first embodiment, heat circulation efficiency is low. Therefore, wettability between the soldering metal 70R and the terminals is degraded and wettability between the soldering metal 70R and the metal patterns is also degraded. Accordingly, in the comparative example, reliability of connection is degraded.

### Second Embodiment

The flexible board 60 according to the second embodiment is the same as that illustrated in FIG. 3A. The semiconductor package according to the second embodiment is the same as that illustrated in FIG. 2.

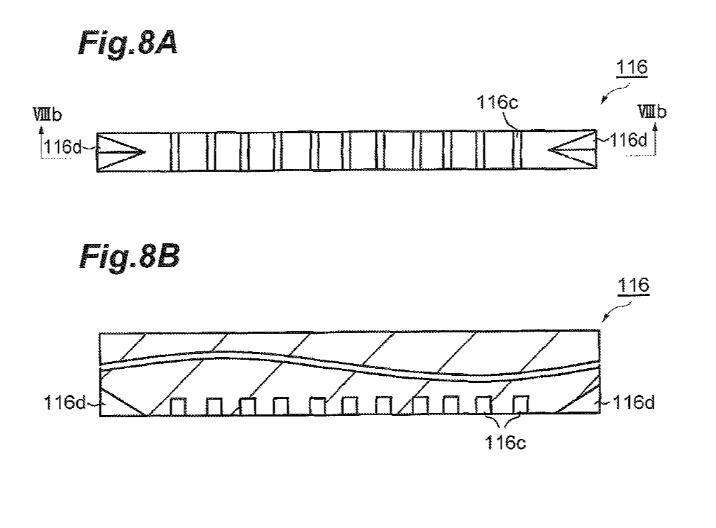

FIG. 8A is a plan view illustrating a lower face of a heater 116. FIG. 8B is a cross-section view along a line VIIIb-VIIIb in FIG. 8A. As illustrated in FIG. 8A and FIG. 8B, a plurality of recesses 116c and two recesses 116d are provided at a tip of the heater 116. The recess 116c has a rectangular shape. The recess 116d has a trigonal pyramid shape. The heater 116 is disposed on the flexible board 60 so that the recesses 116c illustrated in FIG. 8A and FIG. 8B overlap with the via holes 66 illustrated in FIG. 3A, respectively and the recesses 116d overlap with the via holes 68, respectively. As illustrated in FIG. 1 and FIG. 4A, the flexible board 60 is connected to the semiconductor package through soldering.

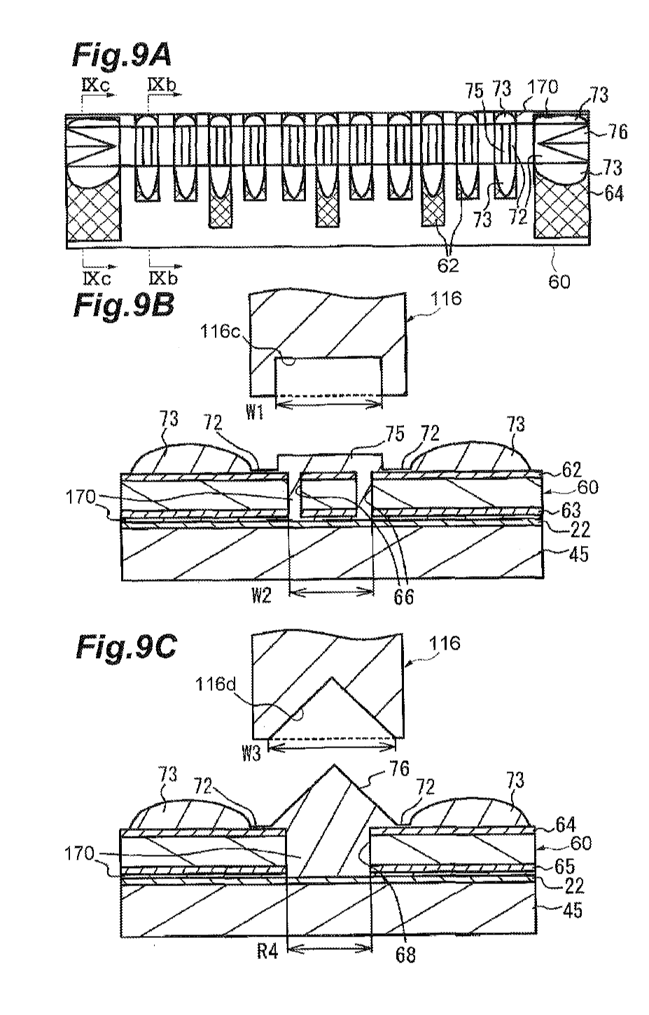

FIG. 9A is a plan view illustrating the flexible board 60 after soldering. FIG. 9B is a cross-section view along a line IXb-IXb in FIG. 9A. FIG. 9C is a cross-section view along a line IXc-IXc in FIG. 9A. As illustrated in FIG. 9A, a soldering metal 170 having projections 75 and 73 and a recess 72 wets and spreads the terminal 62. The soldering metal 170 having projections 76 and 73 and a recess 72 wets and spreads over the terminal 64. Detailed description will be provided with reference to the cross-section view.

As illustrated in FIG. 9B, the melted soldering metal 170 wets and spreads over the terminal 62 provided on the upper face of the flexible board 60 and the terminal 63 provided on the lower face. The melted soldering metal 170 is solidified after intruding into a recess 116c of the heater 116 and forms a rectangular projection 75. As illustrated in FIG. 9C, the soldering metal 170 which has intruded into a recess 116d of the heater 116 is solidified and forms a projection 76 having a trigonal pyramid shape.

Because the soldering metal 170 has the projections 75 and 76, the soldering metal 170 is thick on the via holes 66 and 68. Therefore, the flexible board 60 is rigidly bonded to the signal line 22. A surface area of the soldering metal 170 is larger than one in which there is no projection. Because heat circulation efficiency between the soldering metal on the upper face side and the soldering metal on the lower face side is improved, wettability between the terminals and the soldering metal 170 patterns is improved and wettability between the soldering metal 170 and the metal patterns is also improved. According to the second embodiment, reliability of connection is improved.

As illustrated in FIG. 9B, a width W1 of the recess 116c is greater than a width W2 between outer end portions of two via holes 66. Therefore, the projection 75 is formed over the two via holes 66. Compared to a case where one projection is fanned on one via hole 66, strength of bonding becomes high. Therefore, reliability Of connection is improved. Because the projection 75 is supported on the upper face of the flexible board 60, the shape of the projection 75 becomes stable, which enables rigid bonding. As described above, the recess 116c is preferably provided over a plurality of via holes 66 of the flexible board 60.

As illustrated in FIG. 9C, because a width W3 of a recess 116d is greater than a radius R4 of the via hole 68, the projection 76 which is larger than the via hole 68 is formed. Because the projection 76 is supported on the upper face of the flexible board 60, the shape of the projection 76 becomes stable, which enables rigid bonding. As described above, the recess 116d is preferably larger than the via hole 68.

In the second embodiment, as illustrated in FIG. 3B and FIG. 3C in the first embodiment, the recesses 116c and 116d may have curved upper faces. The projections 75 and 76 may also have spherical faces. That is, it is possible to form the projection 75 which is provided over two via holes 68 and which has a spherical upper face.

In the first embodiment and the second embodiment, the number of via holes 66 formed at one terminal 62 may be one, or three or more. If a plurality of via holes 66 are provided, it is preferable that the recesses of the heaters 16 and 116 overlap with the plurality of via holes 66 as illustrated in the drawings. It is possible to form a projection over the plurality of via holes 66 and improve strength of bonding. It is also possible to provide a plurality of via holes 68 for one terminal 64. By configuring the recesses of the heaters 16 and 116 so as to overlap with the plurality of via holes 68, a recess is formed over the plurality of via holes 68.

The flexible board 60 is made of an insulating material such as a resin. The terminals 62 to 65 are made of a metal such as a laminated film of for example, nickel (Ni) and gold (Au). The soldering metals 70 and 170 are made of a metal such as an alloy of for example, tin and silver (Sn—Ag). The wettability of the terminals 62 to 65 with respect to the soldering metal (wettability of the soldering metal) is preferably higher than the wettability of the soldering metal of the heaters 16 and 116, so as to inhibit the soldering metals 70 and 170 from bonding with the heaters 16 and 116.

The semiconductor package 20 in FIG. 2 includes a light emitting element such as the semiconductor laser 34. According to the first embodiment and the second embodiment, it is possible to form a Transmitter Optical Subassembly (TOSA). The semiconductor package 20 may include, for example, a light receiving element, such as a photodiode. According to the first embodiment and the second embodiment, it is possible to form a Receiver Optical Subassembly (ROSA). As described above, an optical module is formed by soldering the semiconductor package 20 on which optical elements (light emitting element and light receiving element) are mounted to the flexible board 60. It should be noted that it is also possible to manufacture a semiconductor device and an electronic device other than the optical module. The board to which the semiconductor package is soldered is not limited to the flexible board. The semiconductor package may be soldered to any board such as a printed board, which allows input and output of signals and supply of a power-supply voltage.

It should be noted that the present invention is not limited to specific embodiments and examples, and various modification and change can be made within the scope of the gist of the present invention described in the claims.

What is claimed is:

1. A method for manufacturing an electric device, comprising:
applying a wiring board having a first via hole on a mounting face of an object to fix the wiring board;
placing a heater having a recess to the wiring board, the heater being adjusted so that the recess overlaps a boundary between the first via hole and a surface of the wiring board; and
melting a soldering metal so that the soldering metal enters into the recess and the first via hole.

2. The method for manufacturing the electric device according to claim 1, wherein the wiring board has a first face and a second face, the electric device further comprising:
a first terminal provided on the first face of the wiring board; and
a second terminal provided on the second face of the wiring board opposed to the first terminal,
wherein the first via hole overlaps the first and second terminals.

3. The method for manufacturing the electric device according to claim 1, wherein the wiring board has a second via hole, and the recess of the heater is placed on a boundary between the second via hole and the surface of the wiring board.

4. An electric device comprising:
a wiring board having a first via hole on a mounting face of an object to fix the wiring board; and
a soldering metal extending inside the first via hole and on a surface of the wiring board,
wherein the soldering metal has a first projection and a recess of the wiring board located on an outside of the first via hole, and a thickness of the first projection is larger than that of the recess.

5. The electric device according to claim 4, wherein the wiring board has a first face and a second face, the electric device further comprising:
a first terminal provided on the first face of the wiring board; and
a second terminal provided on the second face of the wiring board opposed to the first terminal,
wherein the first via hole overlaps the first and second terminals.

6. The electric device according to claim 4,
wherein the wiring board has a second via hole, and the soldering metal extends inside the second via hole and on the surface of the wiring board, and
wherein the soldering metal has a second projection of the wiring board located on an outside of the first via hole, and a thickness of the second projection is larger than that of the recess.

7. The electric device according to claim 6, wherein the wiring board has a first face and a second face, the electric device further comprising:
a first terminal provided on the first race of the wiring board; and
a second terminal provided on the second face of the wiring hoard opposed to the first terminal,
wherein the second via hole overlaps the first and second terminals.

8. The electric device according to claim 4,
wherein the wiring hoard has a second via hole on a mounting face of an object to fix the wiring board, and
the first projection is provided on the first and the second via holes and on a portion of the wiring board located on an outside of the first and the second via holes.

9. The electric device according to claim 4,
wherein the soldering metal has a third projection located on an outside of the first projection, and the third projection is projecting from the first face, and
the recess is formed between the first projection and the third projection.

10. The electric device according to claim 4,
wherein a cross sectional shape of the first projection is semicircular, triangular or rectangular.
